(19) United States
(12) Patent Application Publication
(10) Pub. No.: US 2004/0246007 A1
(43) Pub. Date: Dec. 9, 2004

(54) Fast, high precision, interference tolerant impedance measurement apparatus

(76) Inventor: Wolfgang Fallot-Burghardt, Mannheim (DE)

Correspondence Address: WOLFGANG FALLOT-BURGHARDT, JOHANN-SCHUETTE-STR. 53, MANNHEIM, D-68307, DE

(21) Appl. No.: 10/452,008

(22) Filed: Jun. 3, 2003

(51) Int. Cl. G01R 27/26

(52) U.S. Cl. 324/667

(57) ABSTRACT

The present invention relates to a fast, high precision, interference tolerant impedance measurement apparatus. The apparatus comprises an oscillator circuit having a characteristic frequency determined by the impedance to be measured. The oscillation voltage is converted by one or more high-gain limiting amplifiers to one or more square waves of the same characteristic frequency. The one or more square waves are down-divided by a frequency division circuit to a second square wave, and afterwards transfered to a time-to-digital converter which converts the period of said second square wave signal to a digital state. The digital state is fed to a digital processing unit, which may perform various functions like mapping the digital state to a digital number, filtering, rejection of scatter values, etc. Finally, a number is output from said digital processing unit which gives a measure for the value of the impedance to be measured.

### BACKGROUND-DESCRIPTION OF PRIOR ART

Sensors to measure physical quantities have become an indispensable means in various fields of engineering. In a considerable number of cases it is the sensor's electrical impedance (i.e. ohmic resistance R, inductance L, or capacitance C) which is affected by the physical quantity of interest. Once transfered to the electrical domain, further signal processing can be done by electrical circuits.

Temperature may be measured by observing the temperature-dependent resistance of silicon or ceramic materials.

The very popular strain gauges are stripes made of resistive materials, often from metals, which are fixedly attached to components, in order to measure quantities as pressure, force, or acceleration. Strain within the component causes the stripes to be compressed or expanded, leading to a change in effective length and width of the stripes and thus to a change of resistance. Strain can also be measured by the piezoresistive effect which is stronger than the effect described before, and is well developed in semiconductors as e.g. silicon.

Magnetic fields alter the resistance of magnetically anisotropic thin films, made of e.g. permalloy, through the magnetoresistive effect. Even stronger, the giant magnetoresistive effect occurs in systems made of a thin spacer layer of a non-magnetic metal between two magnetic metals.

Ferromagnetic materials alter the complex impedance of coils (mainly the inductance) when moved close to them. Conducting materials may also affect the complex impedance of coils (albeit to a much smaller degree) if the latter is driven by alternating currents. This results from eddy currents in the conducting material, which are caused by the coil's alternating magnetic field. Due to the fixed phase relation between the voltage induced in the coil by the eddy currents and the original coil voltage, this effect may be expressed as a change in the coil's complex impedance (i.e. either R or L).

Proximity of conducting or dielectric parts can be measured by measuring capacitance, either directly between a conducting movable part and a second conducting stationary part, or by the change of the ambient capacitance of a stationary part caused by an approaching dielectric object.

It should have become clear that the measurement of a lot of physical quantities can be reduced to the precise measurement of an impedance.

For the measurement of resistive sensors, the Wheatstone bridge circuit has become the preferred choice. For a full Wheatstone bridge circuits, a total of four resistive sensors are needed, where ideally the first pair's impedance would be increased and a second pair's impedance would be decreased at a given time by the physical quantity under measurement (full bridge).

The full Wheatstone bridge offers the advantage of outputting a differental voltage truly linear to the resistance variation, as well as being very symmetric, which gives a great degree of suppression of bridge supply voltage variations, temperature effects, and noise interference. However, the physical quantity to be measured is encoded by voltage amplitude which on principle is more susceptible to interference than a frequency-encoded voltage. There is no inherent limitation of signal bandwith helping in suppressing off-band noise. A Wheatstone bridge's output voltage needs further amplification which must not overly load the bridge. Finally, a four-sensor arrangement is often not feasible on principle given the quantity to be measured; it is more costly and more bulky.

Thus, very often half-bridges with only two, or quarter-bridges with only one variable resistive sensor element are used, with the other resistive sensors being replaced by ordinary resistors. Sometimes, even one of the two voltage dividers of the bridge circuit is omitted altogether, leaving the design non-differential. Although less costly, the symmetry is significantly reduced in all of these case as compared to a full Wheatstone bridge, making the sensor system more susceptible to in particular temperature effects and noise interference. Also, the gain of the bridge is reduced.

In case of imaginary impedance sensors (i.e. capacacitive or inductive sensors), the Wheatstone bridge is usually operated with a sine voltage. The differential output voltage of the bridge thus becomes a sine voltage, too. After amplification of the differential voltage, a bandpass filter may be used to let pass only a frequency interval around the sine wave's frequency, thus suppressing off-band noise. The interval width, however, determines the maximum permissible modulation frequency. A lock-in amplifier which is also frequently used, achieves a similiar bandwith limitation. Apart from the bandwidth argument, the Wheatstone bridge operated with a sine voltage suffers from the same disadvantages as stated for the statically operated Wheatstone bridge.

The two outputs of a Wheatsone bridge are usually fed to a differential amplifier with its output voltage usually being subjected to further analog processing Typical tasks to be acccomplished are lowpass filtering, bandpass filtering, and rectifying in case of sine-voltage operated bridges. Analog processing suffers from the disadvantage of still being susceptible to interference, even though the signal level should be raised and the impedance level should be lowered as compared to the Wheatstone bridge environment. Ideally, differential techniques would be used, effectively doubling the needed space. If the analog processing is to be integrated on a chip, further restrictions apply, e.g. filters with low cut-off frequencies (<1 kHz) can hardly be integrated.

If digital signal processing is to be chosen, the output voltage has to be converted to a digital number making use of an analog-to-digital converter (ADC). The effort of implementing a fast, high-resolution ADC can be tremendous and considerable expertise is needed to design a high performance ADC. The fastest analog-to-digital converter, the flash ADC, employs 2^{N}−1 comparators where N denotes the resolution in bits. Thus, for a ten bit converter, 1023 comparators are needed which becomes very costly. Comparator offset voltages contribute an error source which limits the minimum voltage step per least significant bit (LSB). Other analog-to-digital converter schemes as e.g. successive-approximation ADCs suffer from longer conversion times and thus might not fulfill the high-speed requirements as imposed by the application.

As an alternative to ADCs, time-to-digital converters (TDC) as described by e.g. U.S. Pat. No. 6,396,312 (2002) to Shepston et al. or by numerous publications in the field of High Energy Physics, may be employed to convert analog information to the digital domain. TDCs usually count time intervals defined by a start and a stop signal in units of gate delays. For a 0.35 um CMOS technology, gate delays of 100 ps and below are feasible, indicating the limit of time resolution.

German patent 19,837,331 (1999) to Braun describes a method for measuring rotary speed by making use of a TDC in combination with an RL or RC element, where the imaginary impedance L resp. C is modulated by an “electromagnetically active” material on the wheel. The measurement is achieved by repetitively applying a step voltage to the RL or RC element and monitoring the slew rate which is affected by changes of the imaginary impedance. The slew rate is determined by measuring the time elapsed with a counter or TDC until the slewing voltage reaches a fixed voltage threshold.

This method still suffers from making use of amplitude encoding. It is hard to believe that no jitter should arise in a noisy environment at the point where the slewing voltage reaches the threshold. To somewhat eliminate interference, a differential configuration with two RL or RC elements is proposed—ending up with four impedances again. The TDC approach, however, in combination with a frequency— rather than amplitude-modulated input signal seems to be very promising for detection of very small impedance variations as encountered in e.g. eddy current sensors or strain gauges. Frequency modulation can be achieved by an oscillator whose characteristic frequency is determined by the impedance to be measured. The TDC measures the period precisely and thus permits direct demodulation of the modulation signal. Once in the digital domain, the sensor signal can be further processed, allowing averaging, filtering, sample value rejecting, etc.

Impedance changes due to induced eddy currents can be very small. Using a flat coil with few windings, impedance modulations (resistive and inductive) by a turbine at typical sense distances may be in the range of a few permill only. Very often, such sensors have to operate in a harsh electromagnetic environment, so that interference rejection is crucial. A TDC approach is ideally suited to this task due to its capability to measure very small signals over a big offset, with interference rejection accoplished by digital signal processing.

Strain gauges measure strain in materials making use of Hooke's law, i.e. by measuring the deformation in the material. Maximal elongations are in the range of per mill again, yielding similiar resistance changes. Again, a TDC approach is ideally suited.

### OBJECTS AND ADVANTAGES

Accordingly, several objects and advantages of my invention are

(a) to provide an oscillator, whose oscillation period T depends on the impedance to be measured

(a) to provide an oscillator, being the only analog circuit in the measurement chain,

(c) to provide an oscillator, which limits noise susceptibility to a small frequency band,

(d) to provide an oscillator, which can operate with a single variable sensor element,

(e) to provide a simple and compact means for converting the oscillation period fast and with high precision to a digital state, also called a time-to-digital converter (TDC).

(f) to provide a measurement system comprising an oscillator and a TDC, wherein oscillator amplitude drifts as well as noise spikes during most of the period are rejected, since frequency encoding is employed

(g) to provide a digital signal processing unit which can not be upset unless by strongest interference,

(h) to provide a digital signal processing unit which allows for rejection of scatter measurement values to enhance electromagnetical compatibility (EMC),

(i) to provide a digital signal processing unit which allows for compact implementation of low and high passes with frequencies below 1 kHz,

(j) to provide a digital signal provessing unit with filters of adjustable cut-off frequency.

Still further objects and advantages will become apparent from a consideration of the ensuing description and drawings.

### SUMMARY

The present invention relates to a fast, high precision, interference tolerant impedance measurement apparatus. The apparatus comprises an oscillator circuit having a characteristic frequency determined by the impedance to be measured. The oscillation voltage is converted by one or more high-gain limiting amplifiers to one or more square waves of the same characteristic frequency. The one or more square waves are down-divided by a frequency division circuit to a second square wave, and afterwards transfered to a time-to-digital converter which converts the period of said second square wave signal to a digital state. The digital state is fed to a digital processing unit, which may perform various functions like mapping the digital state to a digital number, filtering, rejection of scatter values, etc. Finally, a number is output from said digital processing unit which gives a measure for the value of the impedance to be measured.

### DRAWINGS

The invention, including objects and advantages thereof, may be best understood by reference to the following detailed description, in combination with the accompanying drawings as follows:

FIG. 1 shows a block diagram of the impedance measurement apparatus.

FIG. 2A shows a first embodiment of a frontend circuit, comprising an oscillator circuit with a characteristic frequency or period being determined by an inductance L or a capacitance C, and a high-gain limiting amplifier to convert the oscillation voltage to a square wave, also called a Schmitt-trigger, and a flip-flop used to half the frequency of the square wave.

FIG. 2B shows a second embodiment of a frontend circuit, comprsing an oscillator circuit of the LC type in greater detail with differential output, two Schmitt-triggers, a jitter cancellation stage, and a frequency division flip-flop.

FIG. 2C shows a third embodiment of a frontend circuit, comprising an oscillator circuit of the RC type with a Schmitt trigger and a frequency division flip-flop.

FIG. 3A shows a first embodiment of a means for converting the period of a square wave to a digital state, also called a time-to-digital converter (TDC), which has been taken from prior art and slightly modified.

FIG. 3B shows a timing diagram for the operation of the TDC shown in FIG. 3A, also taken from prior art.

FIG. 3C shows a second embodiment of a TDC in less detail.

FIG. 4A shows a first embodiment of a digital processing unit with a mapping unit mapping the TDC-state to a binary number, a filter unit with a digital high pass and a limiter, a low-pass unit, and a comparator unit, as well as additional processing.

FIG. 4B shows a second embodiment of a digital processing unit with a mapping unit, a filter unit, and a combined subtraction and division unit.

FIG. 5 shows a revolution meter making use of an impedance measurement apparatus.

FIG. 6 shows a strain gauge making use of an impedance measurement apparatus.

### DETAILED DESCRIPTION

Those skilled in the art will recognize that the drawings provided contain simplifications to better illustrate the concept of the present invention. The present disclosure is to be considered as an example of the principles of the invention and not intended to limit the invention to the specific embodiments shown and described.

It should be noted that in accordance with rules commonly employed in drawing electrical circuit schematics, junctions of three lines indicate an electrical connection between all lines, whereas junctions of four lines indicate crossings of two wires without an electrical connection of the two wires.

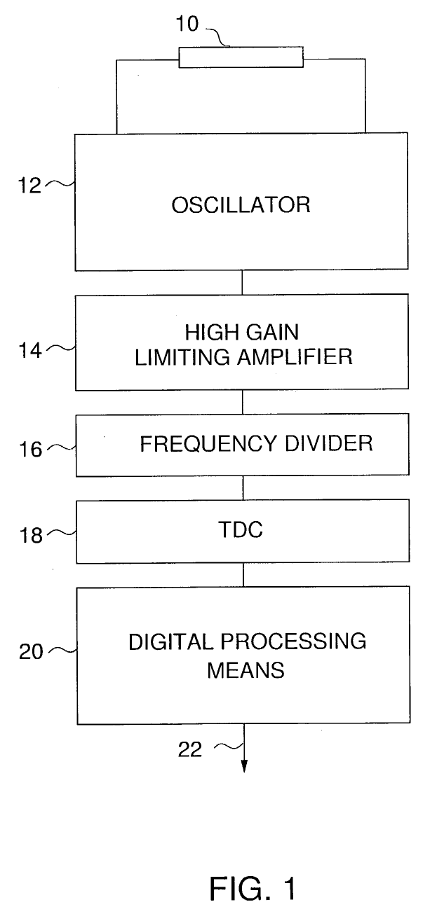

FIG. 1 gives a comprehensive view of my invention. The invention comprises an oscillator circuit 12 having a characteristic frequency determined by an impedance 10 which is the impedance to be measured. The oscillation voltage is converted by one or more high-gain limiting amplifiers 14 to one or more square waves of the same characteristic frequency. The one or more square waves are down-divided by a frequency division circuit 16 to a second square wave, and afterwards transfered to a time-to-digital converter (TDC) 18 which converts the period of said second square wave signal to a digital state. The digital state is fed to a digital processing means 20, which may perform various functions like mapping the digital state to a digital number, filtering, rejection of scatter values, etc. Finally, a number 22 is output from said digital processing unit which gives a measure for the value of impedance 10.

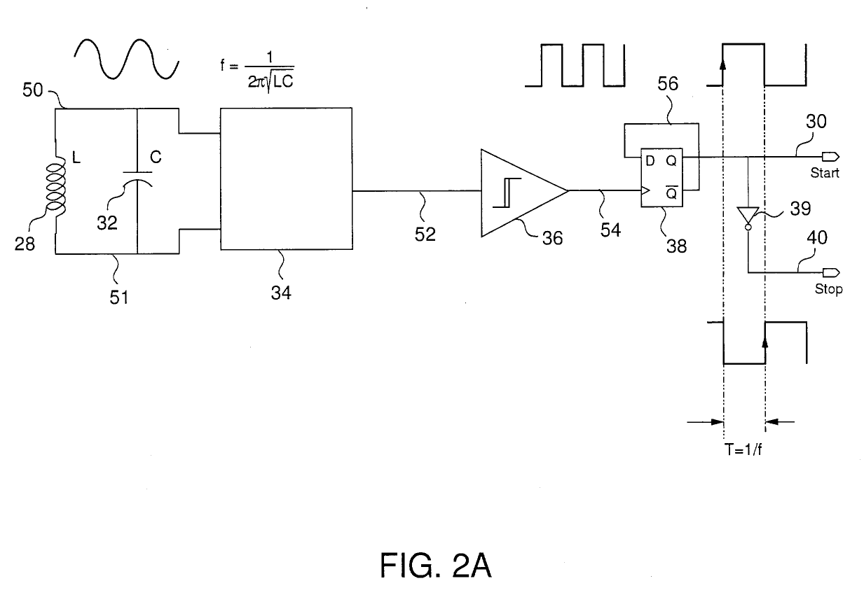

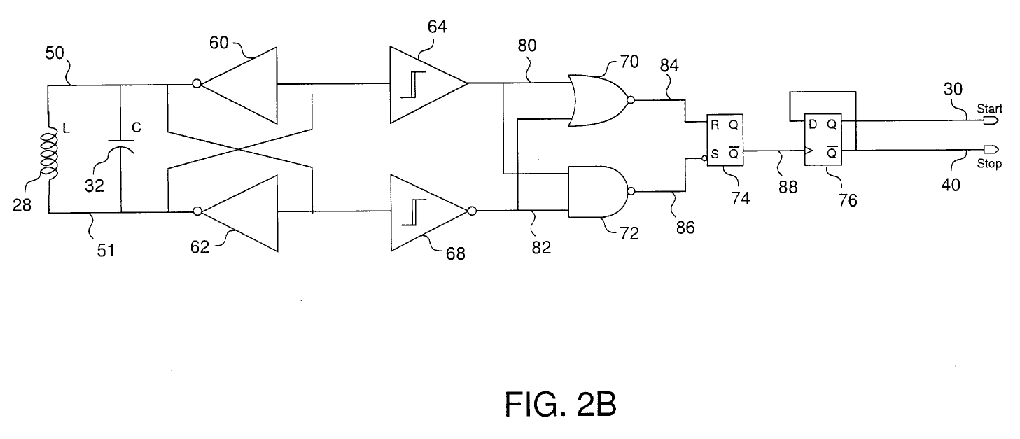

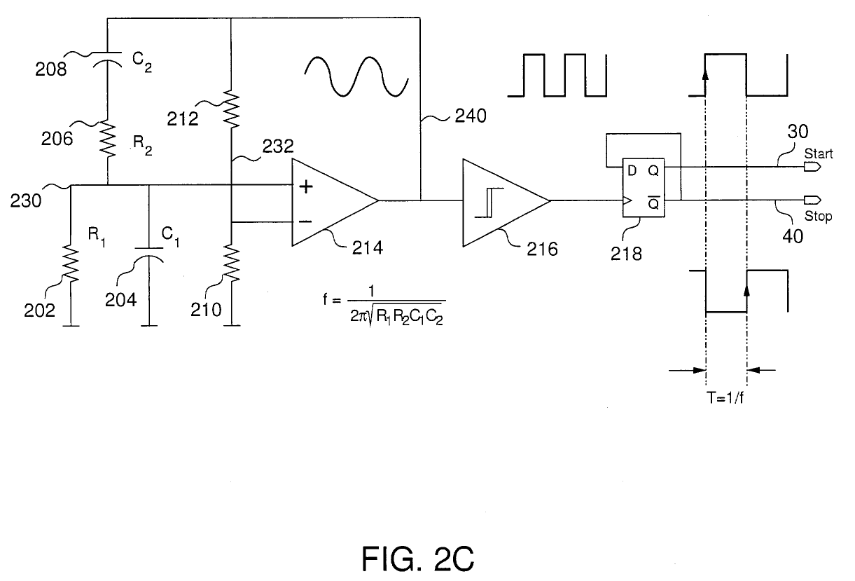

FIG. 2A shows a first embodiment of a frontend circuit, comprising oscillator circuit 12, high-gain limiting amplifier 14, and frequency division circuit 16. Oscillator 34 is of the LC-type with a characteristic frequency determined by inductance 28 (L) and capacitance 32 (C) according to the formula

$$f = \frac{1}{2 π \sqrt{LC}} .$$

Oscillators of the LC-type are well known to people skilled in the art so that a more detailed desciption is omitted here. Either inductance 28 or capacitance 32 can be regarded as impedance 10 according to this invention. The sinusoidal oscillation voltage is apparent on node 50, node 51, and on the output node 52 of oscillator 34, the latter being also the input to Schmitt trigger 36 which forms the high-gain limiting amplifier 14 in the present embodiment. The signal apparent on node 54 thus becomes a square wave of the same characteristic frequency as exhibited by the oscillation of oscillator 34. The output of Schmitt trigger 36 is connected to the clock input of D flip-flop 38 via node 54. By connecting the output \overline{Q} of D flip-flop 38 to the D input of D flip-flop 38 via node 56, D flip-flop 38 is in toggling configuration, with the effect that its outputs Q and \overline{Q} change state with every rising signal edge of node 54, whereby a square wave of half the characteristic frequency is output on node 30. D flip-flop 38 with feedback node 56 thus works as frequency division circuit 16, with a division ratio of two. Inverter 39 creates an inverted copy of the signal apparent on node 30 on node 40. The rising edge of the square wave signal on node 30 denotes the start point of time for the subsequently performed time measurement, the rising edge of the square wave signal on node 40 denotes the stop or halt point of time for the subsequently performed time measurement.

In the following, refering to a node label shall both denote the physical node (wire) as well as the electrical signal apparent on the same physical node, e.g. when referring to “signal 30”, it is referred to the signal apparent on node 30.

Even though a division by two is described, this should not be construed as limiting in scope; the invention embraces other integer division ratios too, as is indicated in the claims.

FIG. 2B shows a second embodiment of a frontend circuit, comprising oscillator circuit 12, high-gain limiting amplifiers 14, and frequency division circuit 16. The oscillator 12, being of the LC type again, comprises inductance 28, capacitance 32, inverting amplifier 60, inverting amplifier 62, and differential output nodes 50 and 51. Said signals 50 and 51 are in anti-phase, i.e. they are shifted by 180° w.r.t each other. Signals 50 and 51 connect to Schmitt trigger with inverted output 68 and Schmitt trigger 64, respectively, which transfer the anti-phased sinusoidal voltages 50 and 51 to square waves of equal frequency and phase. Schmitt trigger output signals 80 and 82 are connected to both the inputs of both NOR gate 70 and NAND gate 72. Nodes 84 and 86 connect the outputs of gates 70 and 72 to the R input and the inverted S input of RS flip-flop 74. At the outputs Q and \overline{Q} of RS flip flip 74, a glitch-free square wave of the characteristic frequency can be obtained. The output \overline{Q} of RS flip flip 74 is connected via node 88 to D flip flop 76, which outputs a square wave of half the characteristic frequency as in the previous embodiment.

Using the shown differential architecture for oscillator 12 in combination with gates 70, 72, and 74 has the advantage of being more robust to electrical interference which may enter into leads 50 and 51. A sudden voltage step due to interference on either lead 50 or lead 51, or simultaneously on both leads 50 and 51 in the same direction, but not necessarily of same amplitude, might cause one and only one of Schmitt triggers 64 or 68 to erroneously trip. In ideal operation, signals 80 and 82 would either be both low or both high, which would reset or set RS flip flop 74, respectively. If signals 80 and 82 became inconsistent due to an interference event, RS flip flop 74 would sustain the old level, and thus reject the noise event.

In practice, even in normal operation, Schmitt trigger 64 and Schmitt trigger with inverted output 68 never trip at the same instant of time. The same mechanism rejecting interference can solve this issue since the Schmitt trigger tripping first is ignored.

Referring to FIG. 2C, a third embodiment of a frontend circuit, comprising oscillator circuit 12, high-gain limiting amplifiers 14, and frequency division circuit 16 is shown. The oscillator circuit, comprising resistors 202, 206, 210, capacitors 204 and 208, and operational amplifier 214 as well as nodes 230, 232, 240, is known in literature as Wien-oscillator and is of the RC type. It is particularly adapted for use in combination with strain gauges. The Wien-oscillator's characteristic frequency f is determined by resistor 202 (R₁), resistor 206 (R₂), capacitor 204 (C₁) and capacitor 208 (C₁) according to

$$f = \frac{1}{2 π \sqrt{{R}_{1} {R}_{2} {C}_{1} {C}_{2}}} .$$

Any of said impedances 202, 204, 206, 208 can be regarded as impedance 10 according to this invention. If resistors 202 and 206 or capacitors 204 and 208 both can be designed to be modulated by the effect to be measured, the impact on the characteristic frequency can be increased.

Further stages 216 and 218 are identical to stages 36 and 38 of FIG. 2A and are not described here again.

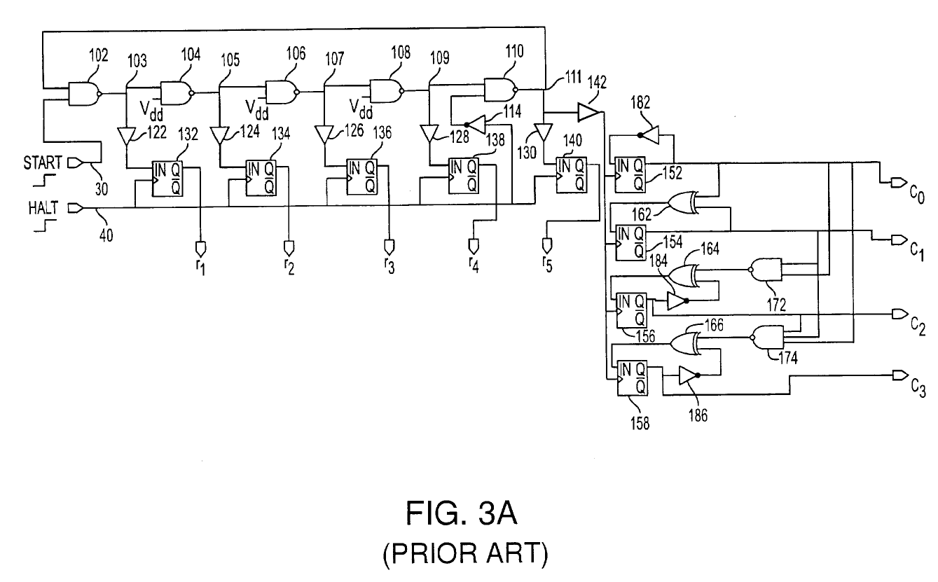

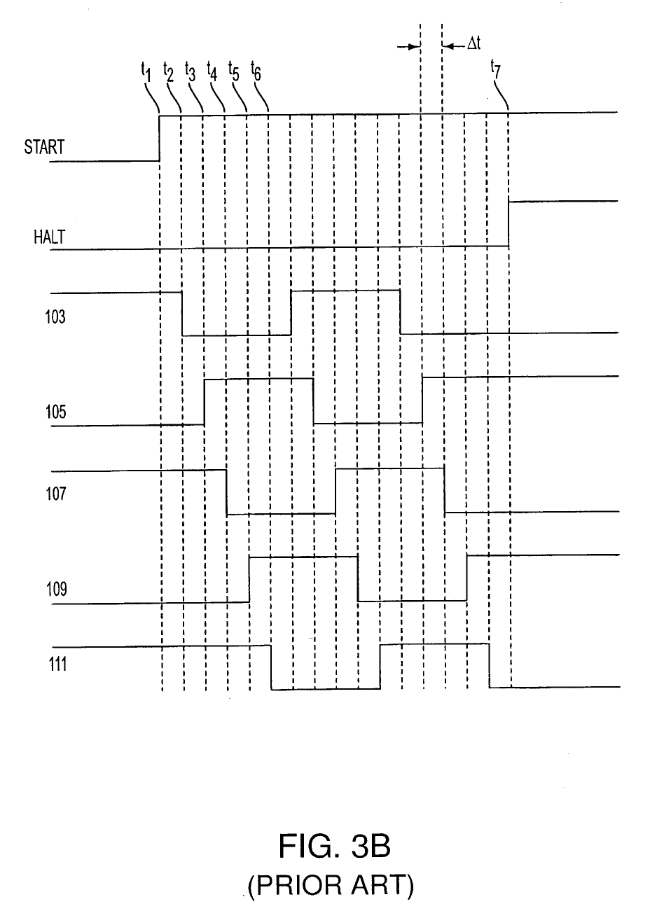

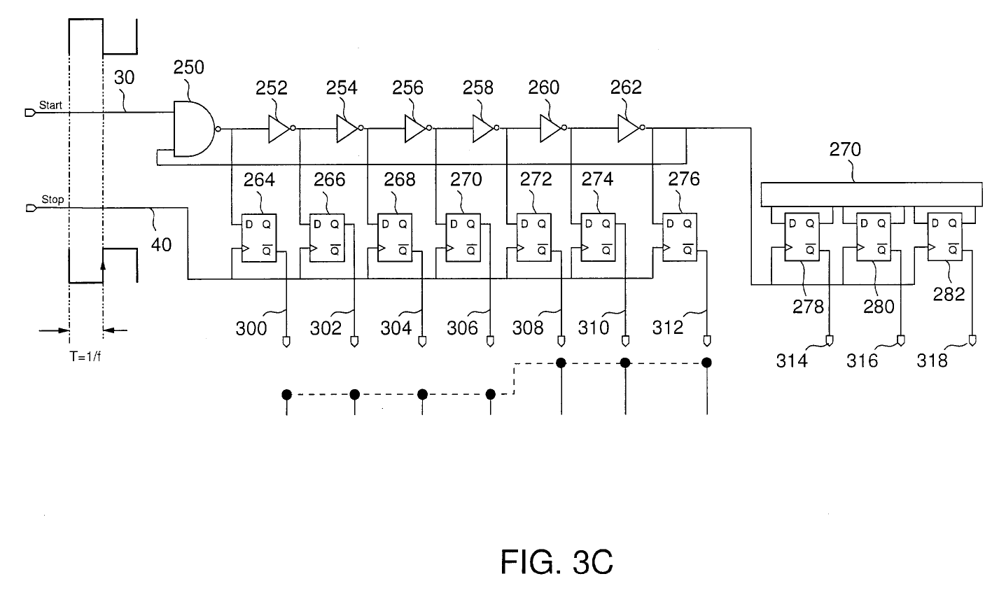

Referring now to FIG. 3A, which has been taken from U.S. Pat. No. 6,396,312 (2002) to Shepston et al. (FIG. 2) and having been slightly modified, a first embodiment of a TDC circuit is shown.

The circuit shown provides the basic function to measure the time elapsed between start signal 30 and halt signal 40 by counting the gate transitions of each of the NAND gates 102, 104, 106, 108, 110, which form a ring oscillator. In general, any odd integer number N of inverting circuits can be used to construct a ring oscillator. If non-inverting gates are used in the ring, oscillation may occur with N being an even number. The ring oscillator begins oscillating upon receipt of start signal 30 and ceases oscillating upon receipt of halt signal 40.

NAND gates 104,106, and 108, by virtue of having an input connected to a logic one (Vdd) behave as simple inverters. NAND gate 102 also behaves as a simple inverter upon receipt of a logic one start signal 30 at its second input. In a similar manner, halt signal 40 is provided through an inverter 114 so that a low going signal at the second input of NAND gate 110 stops the migration of the signal through the ring at NAND gate 110, and thus causes the ring oscillator to stop oscillating.

Various circuit adjustments to facilitate appropriate timing of the circuit may be required to accurately capture the number of gate transitions. For example, the gate delay of the halt signal passing through inverter 114 should be taken into consideration in order to assure that an accurate count from the ring oscillator is achieved.

Ignoring the second input of the NAND gates 102, 104, 106, 108, and 110, one is left with a series connected ring of inverters with each inverter input connected to the output of the preceeding inverter. Each input/output junction is labeled 103, 105, 107, 109, and 111 respectively. The signal at each of these junctions 103, 105, 107, 109, and 111 is provided to a buffer 122, 124, 126, 128, and 130 respectively. These buffers are used to drive the inputs of a set of five (in general N) latches 132,134,136,138, and 140 respectively. Again, those skilled in the art will recognize that any timing associated with buffers 122, 124, 126, 128, and 130 should be accounted for in ensuring that the proper number of gate transitions is properly captured. Latches 132, 134, 136, 138, and 140 each receive the halt signal 40, whereupon they latch in the values present at nodes 103, 105, 107, 109 and 111 to produce values r₁, r₂, r₃, r₄ and r₅ respectively.

The output of the last NAND gate 110 is buffered by buffer 142 and is used as the clock signal for the four latches 152, 154, 156, 158 which together with gates 162, 164, 166, 172, 174, 182, 186 form a ripple counter. Note that in FIG. 2 of U.S. Pat. No. 6,396,312 (2002) to Shepston et al. from where this drawing has been taken, the ripple counter is driven by an inverter whose input is taken from the Q output of latch 140, which does not fulfill the intended aim.

The ripple counter can be of any suitable design and produces binary outputs c₀, c₁, c₂ and c₃ representing the number of tens of gate transitions occurring in the ring oscillator. In other words, the output r₅ is used as a type of overflow indicator with the ripple counter counting the number of cycles occurring in the ring oscillator. The values c₀ through c₃ are fed back and combined through EXCLUSIVE OR (EXOR) gates 162, 164 and 166 as well as NAND gates 172 and 174 along with inverters 182, 184 and 186 in a known manner to provide the binary count C. Any other suitable ripple counter design could also be adapted for use without departing from the present invention.

Thus, in operation a start signal 30 is applied at the input of gate 102 to begin oscillation of the ring oscillator. Upon receipt of a subsequent halt signal 40, the ring oscillator ceases to oscillate and its halted state is captured in latches 132, 134, 136, 238, and 140 with each second signal cycle in the ring oscillator appearing as a count in the ripple counter. The output values r₁ through rs (i.e., R) and c₀ through c₃ (i.e., C) can thus be used to represent the number of gate transitions that have occurred between the time of the start signal and the time of the halt signal. It should be noted, however, that the values of C are in the form of a binary number, while the values of R are not. In order to effectively use the count, many embodiments may require mapping or conversion of the count C+R to a binary (or decimal or other) representation. In other embodiments, these values R and C may be used directly.

The operation of the TDC circuit is illustrated in the timing diagram of FIG. 3B, also taken from U.S. Pat. No. 6,396,312 (2002) to Shepston et al. (FIG. 3) which shows the values of nodes 103, 105, 107, 109 and 111 (or alternately, r₁, r₂, r₃, r₄ and r₅), with time increasing from left to right. At time t₁, the start signal is applied to NAND gate 102 and the logic value appearing at node 103 makes a positive-to-negative transition at time t₂. The amount of time between any two adjacent vertical time lines is given by Δt, which represents one gate transition time. At time t₃, one gate transition time after t₂, the output at node 105 makes a low-to-high transition. Similarly, one gate delay later at time t₄, node 107 makes a high-to-low transition. One-gate delay later at time t₅ node 109 makes a low-to-high transition and at time t₆ node 111 makes a high-to-low transition. At this point in time, each of the inverters in ring oscillator 10 has been triggered and is involved in oscillating. Node 111 provides a new input signal to gate 102 to produce its next transition and so on.

While the above example uses a four bit ripple counter, a ripple counter of any size could be used. Similarly, the number N of inverting circuits used in the ring oscillator can be varied without departing from the scope of the invention.

The oscillations continue until time t₇ at which point the halt signal makes a low-to-high transition. This signal is inverted and applied to AND gate 110, so that this transition ceases the oscillation of the ring oscillator. In addition, the halt signal latches the values of r₁ through r₅ from the nodes 103, 105, 107, 109 and 111 into latches 132, 134, 136, 138 and 140 to the values present at the time of the halt signal. A positive signal transition at node 111 causes the ripple counter to increment. In this simple example, only a count of one is registered in the ripple counter. However, if the halt signal was received at a later time, the ripple counter would count every positive signal transition at node 111 which would then appear as a binary count C.

Referring to FIG. 3C, a somewhat simpler second embodiment of a TDC circuit is shown. Since operation is very similar to the first TDC embodiment described above, the description will be restricted to the differences.

The number of delay stages 250,252,254,256,258,260,262 has been chosen to be seven, but could be any odd integer number N as stated above. In the first embodiment, oscillation is stopped by NAND gate 110, controlled via inverter 114 by halt signal 40. In the second embodiment, no extra gate is needed, since oscillation can be stopped by start signal 30 and NAND gate 250. Buffer amplifiers have been omitted in the second embodiment for reasons of clarity. The outputs 300, 302, 304, 306, 308, 310, 312 of TDC latches 264,266,268,270,272,274,276 are alternatively taken from Q and \overline{Q}, mainly for reasons of better visualization of the stored signal edge. The combinational logic 270 has not been detailed.

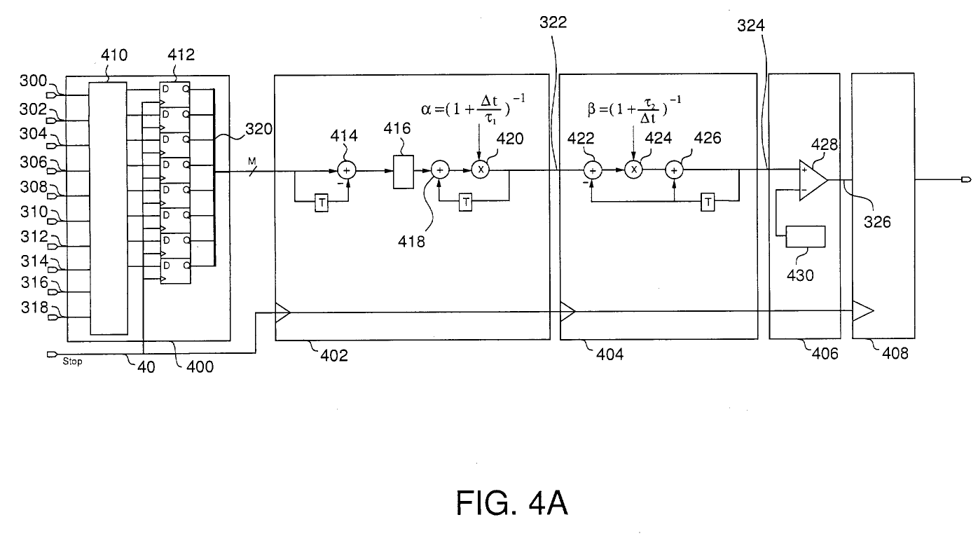

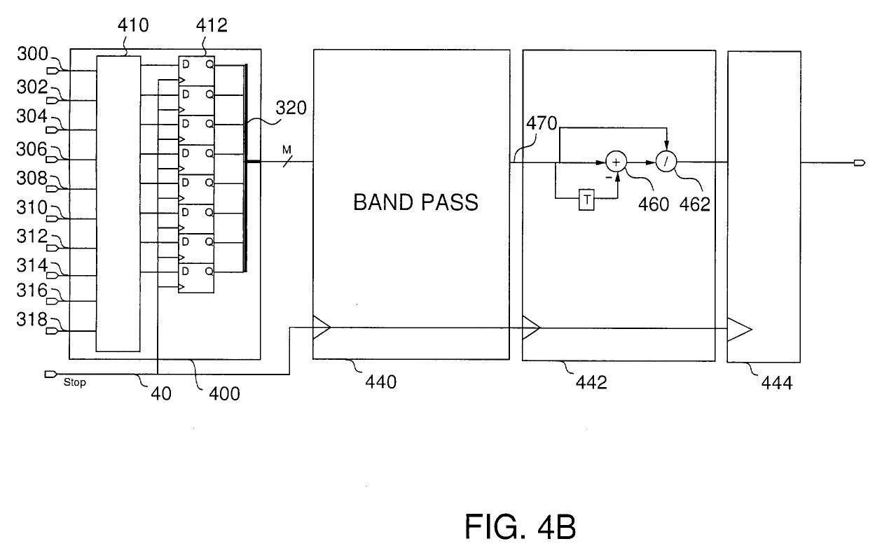

Referring now to FIG. 4A, a first embodiment of a digital processing means 20 is shown. In general, many different embodiments are conceivable without departing from the invention. In particular, various processing blocks or units may be inserted, omitted, swapped, regrouped, etc. Accordingly, it is intended that the present invention embraces all such alternatives, modifications and variations, as fall within the scope of the claims appended.

The first embodiment shown in FIG. 4A is particularly suited to eddy-current sensing of turbine rotation. As a first stage, mapping unit 400 maps signals 300,302,304,306, 308,310,312,314,316,318 from second TDC embodiment via combinational logic 410 to a binary coded value 320 of M bits in M-bit register 412. In drawing 4A, a value of eight has been chosen for M. Various common encoding schemes may be used as e.g. binary one's-complement, binary two's-complement, and binary-coded decimal. The thick line 320 symbolizes a bus of multiple wires in parallel, to which the various output lines of register 412 are bundled. For the rest of the data path, a thin line is employed again, denoting a bus of width as required by the task.

Value 320 is fed to first processing unit 402, clocked by stop signal 40, which acts as a high pass with intermixed limiting function, as will be explained in the following. Value 320 belonging to previous clock pulse t−1 is subtracted from value 320 at current clock pulse t by subtraction unit 414. The difference value received is fed to limiter 416 which passes values within a predetermined window, and rejects (i.e. maps to zero) all incoming values exceeding said window. The output of limiter 416 is fed to adder 418 where summing takes place with the output of first processing unit 402 belonging to previous clock pulse t−1. The resulting value is multiplied by predetermined number α, wherein α depends on the ratio of desired high pass border frequenc τ₁ and clock period Δt according to

$$α = {( 1 + \frac{Δ t}{{τ}_{1}} )}^{- 1} .$$

Finally, the multiplied value is output to second processing unit 404.

First processing unit 402 without the limiter 416 would form a straight one-pole (digital) high-pass. It is the limiter's task to eliminate scatter values, which may arise from signal disturbance in any stage before unit 402.

Second processing unit 404, connected via node 322 to first processing unit 402, forms a one-pole (digital) low pass to filter out frequencies lying above the signal band. It consists of adder 422, muliplier 424 and adder 426. Digital comparator 428 within third processing unit 406 compares value 324 to value 430 and outputs a one or a zero depending on the result.

Finally, third processing unit 408 comprises additional processing tasks as e.g. performing checks on demodulated signal 326, performing frequency division, or suppressing “double peaks” (a special feature encountered with Titanium turbines).

Referring to FIG. 4B, a second embodiment of digital processing means 20 is shown being particularly suited to strain gauges. It comprises, connected in a chain, mapping unit 400, first processing unit 440 acting as a band pass, second processing unit 442 acting as a subtraction and division circuit, and finally third processing unit 444 for backend processing.

Mapping unit 400 has been explained before; processing unit 440 acts as a band pass filter and could be implemented by processing units 402 and 404 in series, or by various other architectures. Processing unit 442 consists of subtraction unit 460 and subsequent division unit 462 which divides the difference value by the absolute value, yielding ΔT/T. ΔT/T is proportional to ΔR/R and thus to material strain as stated in the introduction. Processing unit 444 performs some backend processing.

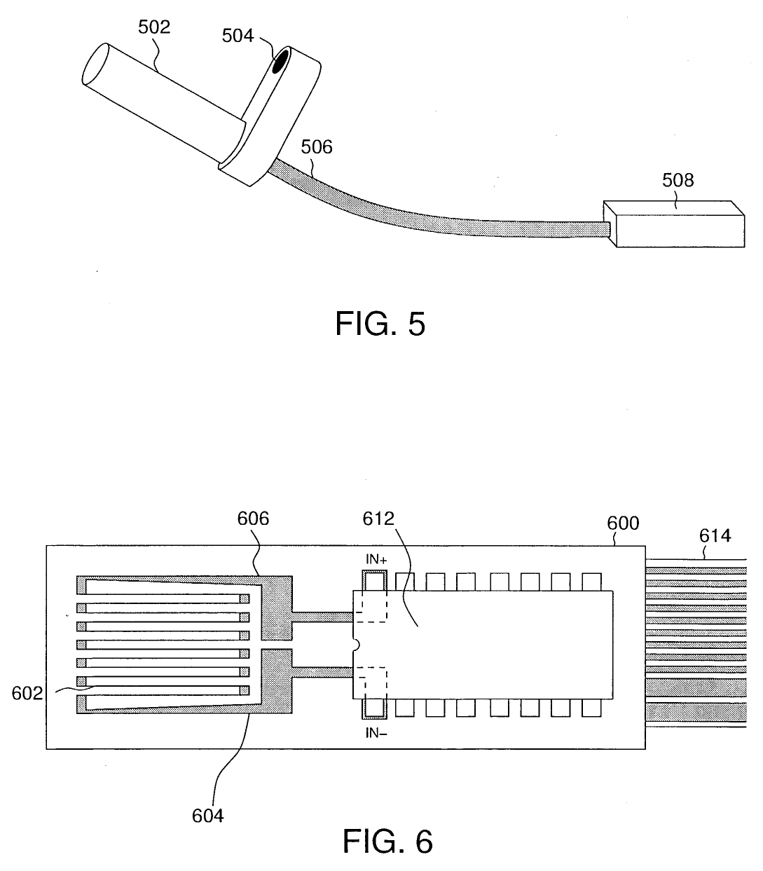

Referring to FIG. 5, a revolution meter for measuring the revolution speed of a turbocharger turbine is shown. Sensor tip 502, usually made of a plastic material, houses sensor coil 28 and can be attached to a fixed frame with a screw through drill hole 504. A shielded cable 506 guides wires 50 and 51 to connector module 508 which houses capacitor 32, the electronics according to this invention, the connector as well as other components required. For cost and space reasons an integrated solution (i.e. a microchip) for the electronics is preferred. In this case, the electronics could also be integrated directly into sensor tip 502, which would be favourable regarding interference susceptibility; however, elevated temperature at the location of the turbocharger turbine prohibit this solution.

A strain gauge is shown in FIG. 6. Resistor 602, which may be resistor 202 or 206 of FIG. 2C, is laid out as a thin line in serpentines, usually made of a metal alloy, on a thin foil 600. The supply lines 604,606 have been laid out broader to limit their impact on the resistance value measured. The electronics according to this invention have been integrated in integrated circuit or chip 612, with the output being an eight bit bus. The wiring from chip 612 to flat connection cable 614 has not been detailed.

### CONCLUSION, RAMIFICATIONS, AND SCOPE

Although the description given above contains many specifities, these should not be construed as limiting the scope of the invention but as merely providing illustrations of some of the presently preferred embodiments of this invention. For example, the invented measurement apparatus could be used to measure any other physical effect leading to a modulation of an impedance; a plurality of such effects has been mentioned in the background section.

Another embodiment of the frontend part would comprise the differential oscillator circuit of FIG. 2B, with nodes 50, 51 connected to inverting and noninverting inputs of a comparator. Since the impedance seen by interference on both leads is equal, interference should affect the voltage on both leads 50 and 51 by to the same amount, which is commonly expressed as common mode. Since an ideal comparator supresses common mode, the comparator's output signal could be fed directly to the frequency divison circuit.

The TDC embodiments shown in FIGS. 3A and 3C may suffer from temperature or voltage drifts which often do not matter since low frequency drifts are out of the permitted signal band. If this is not the case, an absolute measurement could be achieved through an auxiliary reference TDC, measuring a stable reference frequency as created e.g. by a quartz oscillator, and using the value for calibration of the value measured by the main TDC. Likewise, a TDC could be employed with adjustable delay elements, with the manipulated variable derived from a ring oscillator using delay elements of the same type, operated in a phase-locked-loop (PLL) with a quarz-stabilized clock.

Thus, the scope of the invention should be determined by the appended claims and their legal equivalents, rather than by the examples given.

1. An electronic circuit, comprising
an impedance,
an oscillator circuit exhibiting a signal oscillation with a characteristic frequency or period being determined by said impedance,
at least one high-gain limiting amplifier for converting said signal oscillation into one or more first square wave signals, whereby all said one or more first square wave signals exhibit said characteristic frequency or period,
a frequency division circuit generating a second square wave from said one or more first square wave signals, having a period being an integer multiple of said one or more first square waves' period,
means for converting the period of said second square wave to a digital state,
means for digital processing of said digital state,
whereby the value output by said means for digital processing gives a measure for the value of said impedance.

2. The circuit of claim 1, wherein said means for converting the period of said second square wave to a digital state comprises
a plurality of delay elements, each of said delay elements having at least one input and at least one output,
said delay elements being connected to each other input to output so that a closed loop is formed,
a plurality of first storage elements each having one data input and one clock input and at least one data output,
one or more connection elements each having at least one input and at least one output,
at least one of the outputs of said delay elements being connected to said data input of at least one of said first storage elements via one out of said one or more connection elements,
a start signal derived from said second square wave via one out of said one or more connection elements,
means for receiving said start signal for permitting signal propagation in said closed loop of said delay elements,
a stop signal derived from said second square wave via one out of said one or more connection elements and being connected to said clock inputs,
whereby the signal state stored in the first storage elements at arrival of an appropriate signal transition on said stop signal gives a measure for the period of said second square wave.

3. The circuit of claim 2, wherein said means for digital processing comprises a mapping unit, having an output, for mapping the signal state in the first storage elements to a number in binary representation, whereby the period of said second square wave can be obtained in binary representation from the output of said mapping unit.

4. The circuit of claim 3, wherein said binary representation is selected from the group consisting of binary one's-complement, binary two's-complement, and binary-coded decimal.

5. The circuit of claim 3, wherein said means for digital processing comprises one or more processing units, having an input and an output, with the input of first of said one or more processing units being connected to the output of said mapping unit, and said one or more processing units being connected to each other input-to-output.

6. The circuit of claim 5, wherein one out of said one or more processing units comprises a digital comparator for comparing the value received on the input of said one out of said one or more processing units to a binary encoded reference voltage, thereby outputting a square waveform.

7. The circuit of claim 5, wherein one out of said one or more processing units comprises a subtraction unit for subtracting two subsequent numbers received on the input of said one out of said one or more processing units, whereby only the difference of said two subsequent numbers received is output.

8. The circuit of claim 5, wherein one out of said one or more processing units comprises a subtraction unit having an output, for subtracting two subsequent numbers received on the input of said one out of said one or more processing units, and a limiter unit with an input, the input of said limiter unit being connected to the output of said subtraction unit, for suppressing numbers from the output of said subtraction unit exceeding a predetermined interval window, thereby eliminating scatter values.

9. The circuit of claim 5, wherein one out of said one or more processing units comprises a subtraction unit having an output, for subtracting two subsequent numbers received on the input of said one out of said one or more processing units, and a divisional unit with two inputs, the first input of said divisional unit being connected to the output of said subtraction unit, and the second input of said divisional unit being connected to the input of said one out of said one or more processing units, for dividing the number received on the first input by the number received on the second output, whereby only the relative difference of said two subsequent numbers received is output.

10. The circuit of claim 5, wherein at least one out of said one or more processing units is a filter unit for filtering the stream of numbers input to said filter unit.

11. The circuit of claim 10, wherein said filter unit comprises at least one low-pass filter.

12. The circuit of claim 10, wherein said filter unit comprises at least one high-pass filter.

13. The circuit of claim 10, wherein said filter unit comprises at least one band-pass filter.

14. The circuit of claim 2, wherein said one or more connection elements are selected from the group consisting of single delay elements, multiple delay elements connected in a chain, and straight connections.

15. The circuit of claim 14, wherein the delay element is a logical gate.

16. The circuit of claim 14, wherein the delay element is an inverting circuit.

17. The circuit of claim 2, wherein said at least one high-gain limiting amplifier is a Schmitt trigger.

18. The circuit of claim 2, wherein said at least one high-gain limiting amplifier is a comparator.

19. The circuit of claim 2, wherein said means for receiving said start signal comprises a logical gate having two inputs, with a first of said two inputs being connected to one of said delay elements of said closed loop, and a second of said two inputs being connected to said start signal whereby said start signal enables cyclic signal propagation through said closed loop.

20. The circuit of claim 2, further including a loop counter, comprising
a plurality of second storage elements each having one data input and one clock input and at least one data output,
the clock inputs of the second storage elements being connected to at least one of the outputs of said delay elements of said closed loop via a connection element,
a combinational logic connected between the data outputs of the second storage elements and the data inputs of the second storage elements,
whereby the number of cycles a signal propagates through said closed loop of said delay elements is counted.

21. The circuit of claim 20, wherein said one or more connection elements are selected from the group consisting of single delay elements, multiple delay elements connected in a chain, and straight connections.

22. The circuit of claim 2, wherein said impedance is selected from the group consisting of inductances, capacitances, and ohmic resistances.

23. A revolution meter for measuring the revolution speed of a spinning wheel, comprising
the electronic circuit of claim 2, wherein said impedance is modulated by geometrical nonuniformities of said spinning wheel revolving in proximity to the impedance,
mechanical means for carrying and protecting said electronic circuit of claim 2,
whereby the impedance modulation is employed for measuring the rotational speed of the spinning wheel.

24. The revolution meter of claim 23, wherein said spinning wheel is a turbine, and said geometrical nonuniformities are formed by blades and gaps of the turbine.

25. A strain gauge for measuring the deformation of a component, comprising
the electronic circuit of claim 2, wherein said impedance is a resistance,
said resistance being fixedly attached to said component and being modulated by said deformation of said component,
mechanical means for carrying and protecting said electronic circuit of claim 2,
whereby the resistance modulation is employed for measuring the strain within said component.
